(19) United States
(12) Patent Application Publication
(10) Pub. No.: US 2026/0330238 A1
(43) Pub. Date: Oct. 22, 2026

(54) TRAINING SYSTEM, TRAINING METHOD, PREDICTING SYSTEM, PREDICTING METHOD, COMPUTER READABLE RECORDING MEDIUM WITH STORED PROGRAM, AND NON-TRANSITORY COMPUTER PROGRAM PRODUCT

(71) Applicant: REALTEK SEMICONDUCTOR CORP., Hsinchu (TW)

(72) Inventors: Chao-Wei Lin, Hsinchu (TW); Zhi-Hong Huang, Hsinchu (TW)

(73) Assignee: REALTEK SEMICONDUCTOR CORP., Hsinchu (TW)

(21) Appl. No.: 19/436,763

(22) Filed: Dec. 30, 2025

(30) Foreign Application Priority Data
Apr. 21, 2025 (TW) 114115053

(51) Int. Cl. G06N 3/09; G06F 30/367; G06N 3/04

(52) U.S. Cl. CPC G06N 3/09; G06N 3/04; G06F 30/367

(57) ABSTRACT

A training system, a training method, a predicting system, a predicting method, a computer readable recording medium with a stored program, and a non-transitory computer program product are provided. The training method is executed by a processing module. A module to be trained includes a neural network model and a plurality of parameters. The training method includes executing the following steps: receiving training data, where each piece of training data includes training input data and label data, the training input data includes a stress time, a plurality of element ratios corresponding to a plurality of basic elements, a driving strength, and an operating voltage of one of a plurality of benchmark circuits, and the label data includes a speed degradation ratio; and training the module to be trained based on the training data.

### CROSS-REFERENCE TO RELATED APPLICATION

This non-provisional application claims priority under 35 U.S.C. § 119(a) to Patent Application No. 114115053 filed in Taiwan, R.O.C. on Apr. 21, 2025, the entire contents of which are hereby incorporated by reference.

### BACKGROUND

### Technical Field

The present disclosure relates to the field of circuit aging simulation and in particular to a technology of applying a neural network to circuit aging prediction.

### Related Art

In the prior art, to find out an influence on a speed of a digital standard cell circuit after aging, it is necessary to perform spice simulation. According to a special spice aging model provided by a semiconductor chip fabrication plant (Fab) and an aging condition (e.g., high temperature operation life (HTOL) or stress condition) of a user, parameters (e.g., Idsat, Vth, etc.) of NMOS or PMOS devices before and after aging can be obtained, and the simulation is carried out again to obtain a speed degradation ratio of digital standard cell circuits to evaluate the final aging speed.

### SUMMARY

In view of this, some embodiments of the present disclosure provide a training system, a training method, a predicting system, a predicting method, a computer readable recording medium with a stored program, and a non-transitory computer program product to alleviate the problems in the prior art.

Some embodiments of the present disclosure provide a training system, including a processing module and a module to be trained; where the processing module is configured to receive training data, each piece of training data includes training input data and label data, the training input data includes a stress time, a plurality of element ratios corresponding to a plurality of basic elements, a driving strength, and an operating voltage of one of benchmark circuits, and the label data includes a speed degradation ratio; and the module to be trained includes a neural network model and a plurality of parameters; the module to be trained is configured to receive a network input and generate a network output based on the network input, the neural network model, and the parameters; and the processing module is configured to train the module to be trained based on the aforementioned training data.

Some embodiments of the present disclosure provide a training method, used for training a module to be trained, and executed by a processing module, where the module to be trained includes a neural network model and a plurality of parameters; the module to be trained is configured to receive a network input and generate a network output based on the network input, the neural network model, and the aforementioned parameters; and the training method includes executing the following steps: receiving training data, where each piece of training data includes training input data and label data, the training input data includes a stress time, a plurality of element ratios corresponding to a plurality of basic elements, a driving strength, and an operating voltage of one of a plurality of benchmark circuits, and the label data includes a speed degradation ratio; and training the module to be trained based on the training data.

Some embodiments of the present disclosure provide a predicting system, including a neural network module and a predicting processing module, where the neural network module includes a predicting neural network model, the predicting neural network model being configured to have a same architecture as that of the neural network model; the neural network module is configured to store the parameters obtained after training by the aforementioned training system and is configured to receive an input to be predicted, and generate a predicted output of the input to be predicted based on the input to be predicted, the predicting neural network model and the aforementioned parameters; and the predicting processing module is configured to input a piece of feature data of a circuit to be predicted as the input to be predicted to the neural network module to obtain the predicted output, where the feature data includes a stress time, a plurality of element ratios corresponding to basic elements, a driving strength, and an operating voltage of the circuit to be predicted.

Some embodiments of the present disclosure provide a predicting method, including: inputting, by a predicting processing module, a piece of feature data of a circuit to be predicted as an input to be predicted to a neural network module, where the feature data includes a stress time, a plurality of element ratios corresponding to basic elements, a driving strength, and an operating voltage of the circuit to be predicted; and receiving, by the neural network module, the input to be predicted, and generating a predicted output of input data to be predicted based on the input to be predicted, a predicting neural network model of the neural network module, and parameters obtained by training by the aforementioned training method, where the predicting neural network model has a same architecture as that of the neural network model.

Some embodiments of the present disclosure provide a computer-readable medium with a stored program and a non-transitory computer program product, where the program, after loaded and executed by a processing unit, can implement the aforementioned training method.

Based on the above, some embodiments of the present disclosure provide a training system, a training method, a predicting system, a predicting method, a computer-readable recording medium with a stored program, and a non-transitory computer program product. By way of training, a plurality of parameters of a neural network model corresponding to basic elements are obtained, and a predicting system applying the aforementioned neural network model and the plurality of parameters of the neural network model can predict a speed degradation ratio when an aging model is not provided in a laboratory; the predicting system applying the aforementioned neural network model and the plurality of parameters of the neural network model can be repeatedly used for predicting aging results of various scenarios with different operating voltages and stress times, thus avoiding the repeated real circuit aging simulation, so that resources and time can be saved.

### BRIEF DESCRIPTION OF THE DRAWINGS

FIG. 1 is a block diagram of a training system illustrated according to an embodiment of the present disclosure.

FIG. 2 is a schematic diagram of a neural network model illustrated according to some embodiments of the present disclosure.

FIG. 3 is a circuit diagram of a benchmark circuit illustrated according to some embodiments of the present disclosure.

FIG. 4 is a schematic diagram of a training input data illustrated according to some embodiments of the present disclosure.

FIG. 5 is a relational graph showing a speed degradation ratio versus a stress time illustrated according to some embodiments of the present disclosure.

FIG. 6 is a schematic diagram of training results illustrated according to some embodiments of the present disclosure.

FIG. 7 to FIG. 10 are schematic diagrams showing performance of a predicting system illustrated according to some embodiments of the present disclosure.

FIG. 11 is a flowchart of training and predicting illustrated according to an embodiment of the present disclosure.

FIG. 12 is a block diagram of a predicting system illustrated according to some embodiments of the present disclosure.

FIG. 13 is a systematic block schematic diagram of an electronic device illustrated according to some embodiments of the present disclosure.

FIG. 14 is a flowchart of a training method illustrated according to some embodiments of the present disclosure.

FIG. 15 is a flowchart of a training method illustrated according to some embodiments of the present disclosure.

FIG. 16 is a flowchart of a predicting method illustrated according to some embodiments of the present disclosure.

### DETAILED DESCRIPTION

For the aforementioned and other technical contents, features and effects of the present disclosure, they are clearly presented in the following detailed descriptions of embodiments with reference schematics. Any modification and change that does not affect the efficacy that the present disclosure can produce and the purpose that can be achieved shall still fall within the scope of the technical content disclosed by the present disclosure. The same labels in all schematics will be used for representing the same or similar elements.

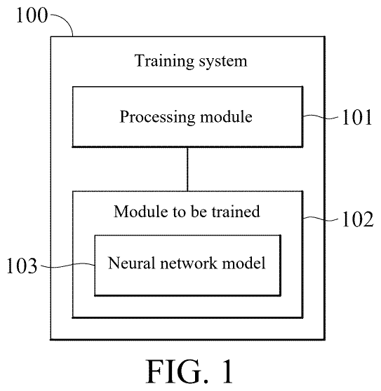

FIG. 1 is a block diagram of a training system illustrated according to an embodiment of the present disclosure. Referring to FIG. 1, a training system 100 includes a processing module 101 and a module to be trained 102. The processing module 101 is configured to receive at least one piece of training data, where each piece of training data includes training input data and label data. The training input data includes a stress time, a plurality of element ratios corresponding to a plurality of basic elements, a driving strength, and an operating voltage of one of benchmark circuits, and the label data includes a speed degradation ratio of the benchmark circuit. The module to be trained 102 includes a neural network model 103 and a plurality of parameters. The module to be trained 102 is configured to receive a network input and generate a network output based on the network input, the neural network model 103, and the parameters. The speed degradation ratio of the benchmark circuit is a ratio of a speed at which the benchmark circuit degrades under an aging condition (e.g., high temperature operation life (HTOL) or stress condition) of a user to a speed at which the benchmark circuit operates normally without being subjected to the aging condition or stress condition of the user. By way of example, if the speed at which the benchmark circuit operates normally without the aging condition or stress condition of the user is 1, and the speed at which the benchmark circuit degrades after being subjected to the aging condition or the stress condition is 0.9, then the speed degradation ratio of the benchmark circuit is 0.9.

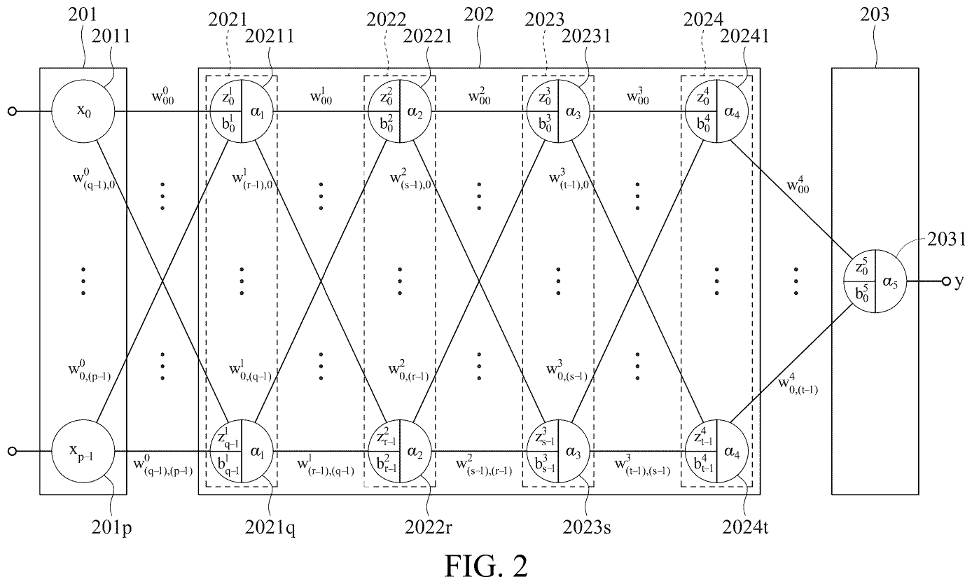

FIG. 2 is a schematic diagram of a neural network model illustrated according to some embodiments of the present disclosure. References are made to both FIG. 1 and FIG. 2. In some embodiments of the present disclosure, the neural network model 103 includes an input layer 201, an intermediate layer 202, and an output layer 203. The input layer 201 includes input neurons 2011 to 201p, where p is a positive integer. The input neurons 2011 to 201p are each configured to receive network input, and an input value obtained by the input neuron 201k is xₖ₋₁, where k=1, 2, . . . , p. The intermediate layer 202 includes four hidden layers: hidden layers 2021 to 2024. The hidden layer 2021 includes neurons 20211 to 2021q; the hidden layer 2022 includes neurons 20221 to 2022r; the hidden layer 2023 includes neurons 20231 to 2023s; and the hidden layer 2024 includes neurons 20241 to 2024t, where q, r, s, and t are each a positive integer. The output layer 203 includes an output neuron 2031. The output layer 203 outputs a network output y.

The input layer 201, the hidden layers 2021 to 2024, and the output layer 203 are connected to each other in a fully-connected manner via a plurality of connection paths. That is, as illustrated in FIG. 2, each of the input neurons 2011 to 201p of the input layer 201 is connected to each of the neurons 20211 to 2021q of the hidden layer 2021 via a connection path; each of the neurons 20211 to 2021q of the hidden layer 2021 is connected to each of the neurons 20221 to 2022r of the hidden layer 2022 via a connection path, . . . , and each of the neurons 20241 to 2024t of the hidden layer 2024 is connected to the output neuron 2031 of the output layer 203 via a connection path.

All the aforementioned connection path all include a weight. In the connection paths for the input layer 201 and the hidden layer 2021, the weight of a connection path for the input neuron 2011 and the neuron 20211 is

$${w}_{00}^{0} , … ,$$

the weight of a connection path for the input neuron 2011 and the neuron 2021q is

$${w}_{( q - 1 ) , 0}^{0} .$$

The weight of a connection path for the input neuron 201p and the neuron 20211 is

$${w}_{0 , ( p - 1 )}^{0} , … ,$$

the weight of a connection path for the input neuron 201p and the neuron 2021q is

$${w}_{( q - 1 ) , ( p - 1 )}^{0} ,$$

and so on.

In the connection paths for the hidden layer 2021 and the hidden layer 2022, the weight of a connection path for the neuron 20211 and the neuron 20221 is

$${w}_{00}^{1} , … ,$$

the weight of a connection path for the neuron 20211 and the neuron 2022r is

$${w}_{( r - 1 ) , 0}^{1} .$$

The weight of a connection path for the neuron 2021q and the neuron 20221 is

$${w}_{0 , ( q - 1 )}^{1} , … ,$$

the weight of a connection path for the neuron 2021q and the neuron 2022r is

$${w}_{( r - 1 ) , ( q - 1 )}^{1} ,$$

and so on. In the connection paths for the hidden layer 2022 and the hidden layer 2023, the weight of a connection path for the neuron 20221 and the neuron 20231 is

$${w}_{00}^{2} , … ,$$

the weight of a connection path for the neuron 20221 and the neuron 2023s is

$${w}_{( s - 1 ) , 0}^{2} .$$

The weight of a connection path for the neuron 2022r and the neuron 20231 is

$${w}_{0 , ( r - 1 )}^{2} , … ,$$

the weight of a connection path for the neuron 2022r and the neuron 2023s is

$${w}_{( s - 1 ) , ( r - 1 )}^{2} ,$$

and so on. In the connection paths for the hidden layer 2023 and the hidden layer 2024, the weight of a connection path for the neuron 20231 and the neuron 20241 is

$${w}_{00}^{3} , … ,$$

the weight of a connection path for the neuron 20231 and the neuron 2024t is

$${w}_{( t - 1 ) , 0}^{3} .$$

The weight of a connection path for the neuron 2023s and the neuron 20241 is

$${w}_{0 , ( s - 1 )}^{3} , … ,$$

the weight of a connection path for the neuron 2023s and the neuron 2024t is

$${w}_{( t - 1 ) , ( s - 1 )}^{3} ,$$

and so on.

In the connection paths for the hidden layer 2024 and the output layer 203, the weight of a connection path for the neuron 20241 and the output neuron 2031 is

$${w}_{00}^{4} , … ,$$

the weight of a connection path for the neuron 2024t and the output neuron 2031 is

$${w}_{0 , ( t - 1 )}^{4} .$$

The neurons 20211 to 2021q, 20221 to 2022r, 20231 to 2023s, and 20241 to 2024t of the intermediate layer 202 and the output neuron 2031 of the output layer 203 all include a bias, a weighted input, and an activation function. As illustrated in FIG. 2, the neuron 20211 has a bias

$${b}_{0}^{1} ,$$

a weighted input

$${z}_{0}^{1} ,$$

and an activation function α₁, . . . , and the neuron 2021q has a bias

$${b}_{q - 1}^{1} ,$$

a weighted input

$${z}_{q - 1}^{1} ,$$

and an activation function α₁; the neuron 20221 has a bias

$${b}_{0}^{2} ,$$

a weighted input

$${z}_{0}^{2} ,$$

and an activation function α₂, . . . , and the neuron 2022r has a bias

$${b}_{r - 1}^{2} ,$$

a weighted input

$${z}_{r - 1}^{2} ,$$

and an activation function α₂; the neuron 20231 has a bias

$${b}_{0}^{3} ,$$

a weighted input

$${z}_{0}^{3} ,$$

and an activation function α₃, . . . , and the neuron 2023s has a bias

$${b}_{s - 1}^{3} ,$$

a weighted input

$${z}_{s - 1}^{3} ,$$

and an activation function α₃; the neuron 20241 has a bias

$${b}_{0}^{4} ,$$

a weighted input

$${z}_{0}^{4} ,$$

and an activation function α₄, . . . , and the neuron 2024t has a bias

$${b}_{t - 1}^{4} ,$$

a weighted input

$${z}_{t - 1}^{4} ,$$

and an activation function α₄; and the output neuron 2031 has a bias

$${b}_{0}^{5} ,$$

a weighted input

$${z}_{0}^{5} ,$$

and an activation function α₅. How the neurons of the intermediate layer 202 and the output layer 203 operate will be illustrated below with the neuron 20211 taken as an example.

The weighted input

$${z}_{0}^{1}$$

is a weighted sum of input values of the input neurons 2011 to 201p of the input layer 201 based on weights and the biases, as shown in the following equation (Eq1):

$${z}_{0}^{1} = {w}_{00}^{0} {x}_{0} + {w}_{01}^{0} {x}_{1} + … + {w}_{0 , ( p - 1 )}^{0} {x}_{p - 1} + {b}_{0}^{1} . \qquad ( Eq1 )$$

The output of the neuron 20211 is

$${α}_{1} ( {z}_{0}^{1} ) .$$

The outputs of the intermediate layer 202 and the output layer 203 are analogized in the aforementioned manner. The activation functions α₁ to α₅ can be preset as required. In some embodiments of the present disclosure, the activation functions α₁ to α₅ are set as a sigmoid function. It is worth noting that the activation functions α₁ to α₅ does not necessarily have to be set as the same function. For example, the activation function α₅ can be set as a function different from the activation functions α₁ to α₄.

In this embodiment, the parameters of the module to be trained 102 include the weights of all the aforementioned connection paths, and the biases of all the neurons and output neurons.

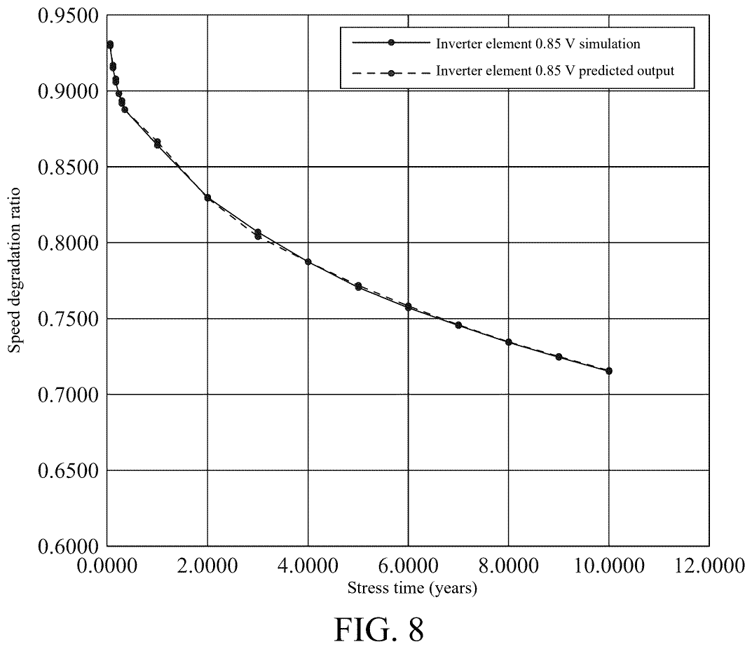

FIG. 11 is a flowchart of training and predicting illustrated according to an embodiment of the present disclosure. Referring to FIG. 11, in some embodiments of the present disclosure, the processing module 101 loads a training dataset 1104 from a database 1100 to train the module to be trained 102. The training dataset 1104 includes the aforementioned at least one training data. The database 1100 includes an aging simulation database 1102 that is completed using an aging simulation of a benchmark circuit 1103 composed of basic elements planned in advance, and a database 1101 for HTOL silicon data measured using a testline of the benchmark circuit 1103 composed of the above-mentioned planned basic elements under the stress time of different HTOLs, and OP voltages.

In some embodiments of the present disclosure, the aforementioned benchmark circuit 1103 is a ring oscillator, where the ring oscillator includes an enable stage and an even number of inverter stages, each of the inverter stages has a same driving strength and each of the inverter stages is composed of one of the aforementioned basic elements. A plurality of element ratios of the benchmark circuit corresponding to a plurality of basic elements in the aforementioned training data are a plurality of composition ratios of the aforementioned inverter stages corresponding to the aforementioned basic elements.

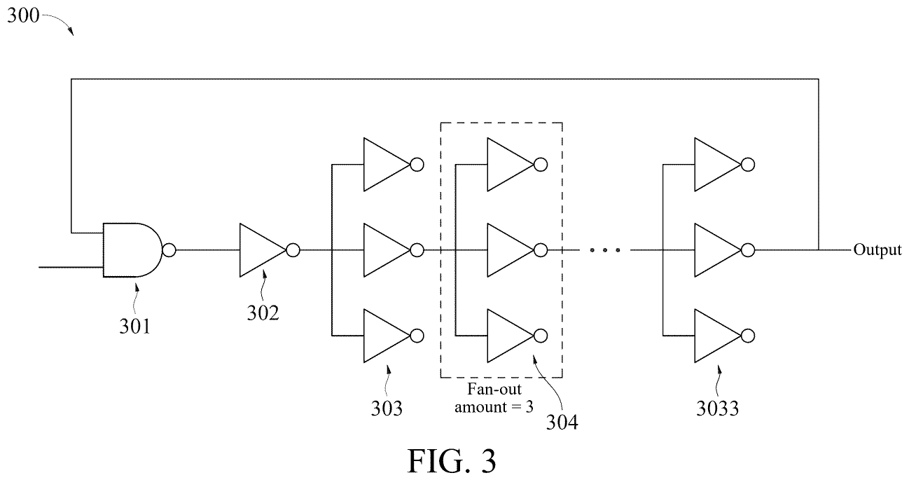

FIG. 3 is a circuit diagram of a benchmark circuit illustrated according to some embodiments of the present disclosure. Referring to FIG. 3, in some embodiments of the present disclosure, the aforementioned basic elements include inverter elements, NAND gate elements, NOR gate elements, and XOR gate elements. The aforementioned ring oscillator is illustrated as a ring oscillator 300. The ring oscillator 300 includes an enable stage 301 and inverter stages 302 to 3033 (i.e., the number of the inverter stages 302 to 3033 is 32). A fan-out amount of each of the inverter stages 302 to 3032 is 3. Each of the inverter stages 302 to 3033 has the same driving strength and each of the inverter stages 302 to 3033 is composed of one of the aforementioned basic elements. In this embodiment, the aforementioned driving strength includes three grades: D1, D2, and D4.

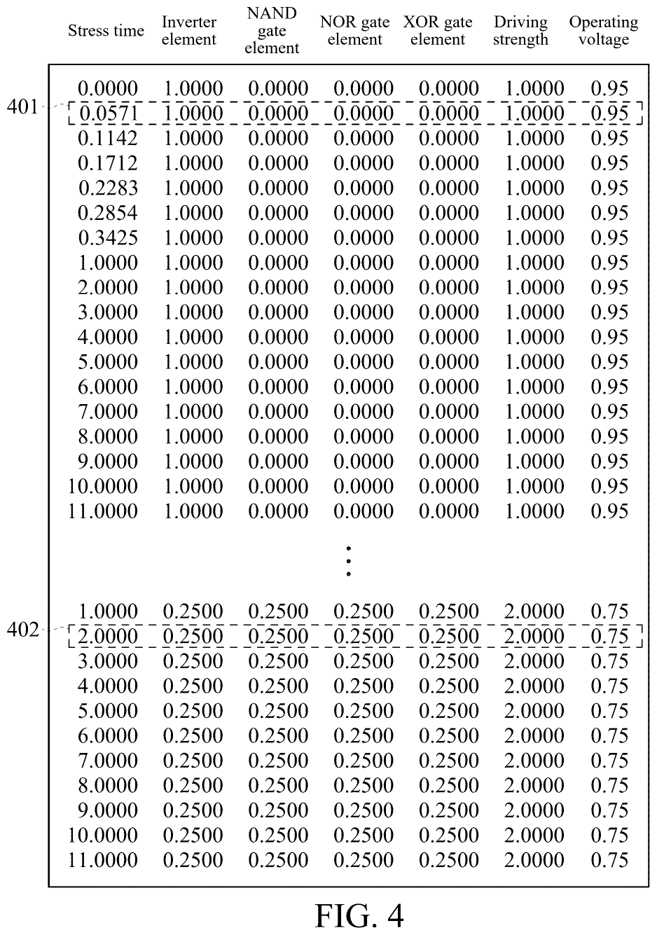

FIG. 4 is a schematic diagram of a training input data illustrated according to some embodiments of the present disclosure. Referring to FIG. 3 to FIG. 4, in some embodiments of the present disclosure, the stress time is measured in years, and the operating voltage is measured in volts. In this embodiment, the numerical values 1, 2, and 4 represent the three grades D1, D2, and D4, respectively. In the training input data 401, the numerical value corresponding to the stress time is 0.0571, which indicates that the stress time for aging simulation is 500 h; the numerical values corresponding to the inverter element, the NAND gate element, the NOR gate element and the XOR gate element are 1.0, 0.0, 0.0, and 0.0, respectively, which indicates that the inverter stages 302 to 3033 are all composed of the inverter elements. The numerical value corresponding to the driving strength is 1.0, which indicates that the driving strength of each of the inverter stages 302 to 3033 is D1. The numerical value corresponding to the operating voltage is 0.95, which indicates that the operating voltage for aging simulation is 0.95 volts. In the training input data 402, the numerical value corresponding to the stress time is 2, which indicates that the stress time for aging simulation is 2 years; the numerical values corresponding to the inverter element, the NAND gate element, the NOR gate element, and XOR gate element are 0.25, 0.25, 0.25, and 0.25, respectively, which indicates that a ratio of ¼ (0.25) of the inverter stages 302 to 3033 are composed of the inverter elements, a ratio of ¼ (0.25) of the inverter stages are composed of the NAND gate elements, a ratio of ¼ (0.25) of the inverter stages are composed of the NOR gate elements, and a ratio of ¼ (0.25) of the inverter stages are composed of the XOR gate elements (for example, the inverter stages 302 to 309 are composed of the inverter elements, the inverter stages 3010 to 3017 are composed of the NAND gate elements, the inverter stages 3018 to 3025 are composed of the NOR gate elements, and the inverter stages 3026 to 3033 are composed of the XOR gate elements). The aforementioned ratios are also referred to as element ratios corresponding to basic elements (in this embodiment, the basic elements are the inverter elements, the NAND gate elements, the NOR gate elements, and the XOR gate elements). The numerical value corresponding to the driving strength is 2.0, which indicates that the driving strength of each of the inverter stages 302 to 3033 is D2. The numerical value corresponding to the operating voltage is 0.75, which indicates that the operating voltage for aging simulation is 0.75 volts.

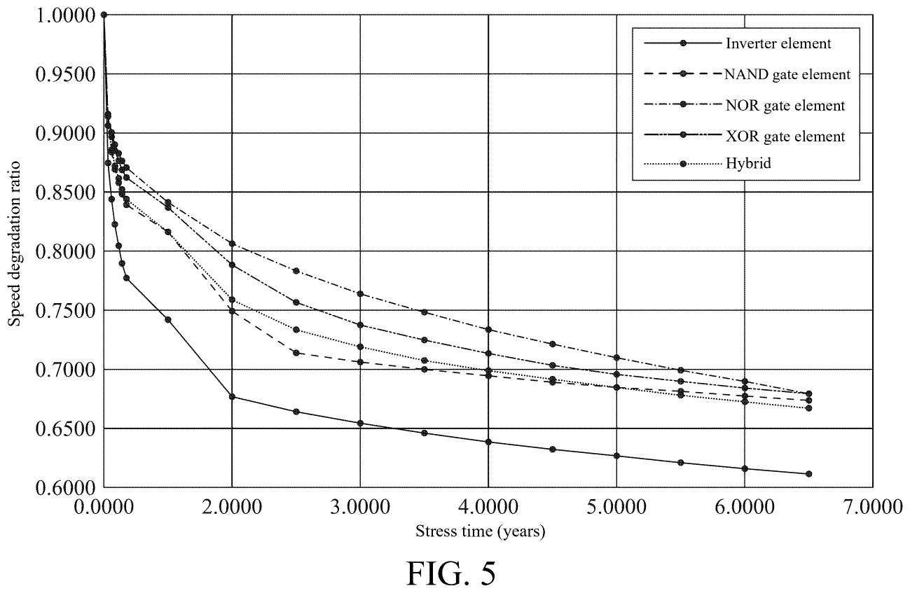

FIG. 5 is a relational graph showing a speed degradation ratio versus a stress time illustrated according to some embodiments of the present disclosure. Referring to FIG. 5, following the aforementioned embodiment in which the benchmark circuit 1103 is a ring oscillator 300 (including an enable stage 301 and inverter stages 302 to 3033 of which the number is 32, and the fan-out amount of each of the inverter stages 302 to 3032 is 3), in the example illustrated in FIG. 5, the operating voltage for aging simulation is 0.95 volts, the temperature of the aging simulation condition is 150° C., and the driving strength of each of the inverter stages 302 to 3033 is D1. The line marked as a hybrid represents that the inverter stages 302 to 3033 are composed of a mixture of the inverter elements, the NAND gate elements, the NOR gate elements, and the XOR gate elements, and the line marked as the inverter element represents that the inverter stages 302 to 3033 are all composed of the inverter elements, and so on.

As can be seen from FIG. 5, on the same benchmark circuit, even if the driving strength, the operating voltage, and the element ratios corresponding to the basic elements (in this embodiment, the basic elements are the inverter elements, the NAND gate elements, the NOR gate elements, and the XOR gate elements) of each of the inverter stage 302 to 3033 are fixed, there is no simple functional relationship between the speed degradation ratio of the benchmark circuit and the stress time.

The training method of some embodiments of the present disclosure and how various modules of the training system 100 cooperate with each other will be described below in details with the schematics.

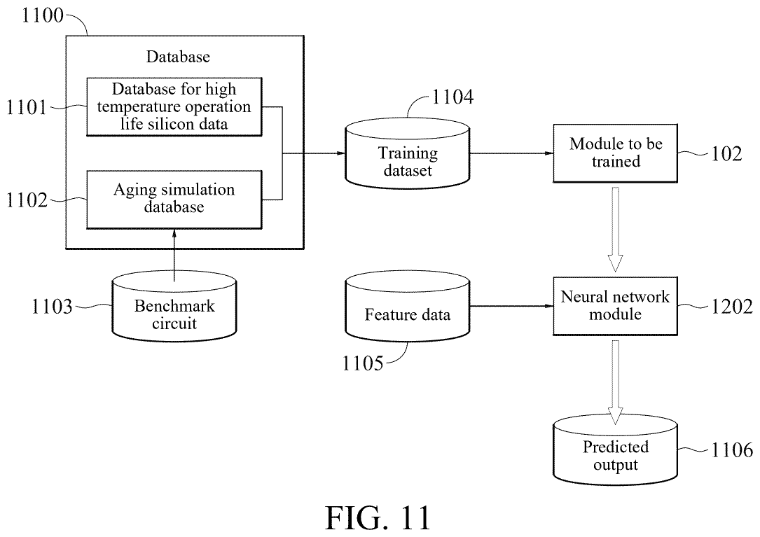

FIG. 14 is a flowchart of a training method illustrated according to some embodiments of the present disclosure. Referring to FIG. 1, FIG. 2, and FIG. 14, in the embodiment illustrated in FIG. 14, the training method is executed by the processing module 101, and is used for training the module to be trained 102. The training method includes executing steps S1401 to S1402 by the processing module 101. In step S1401, at least one piece of training data is received, where each piece of training data includes training input data and label data. The training input data includes a stress time of one (e.g., the ring oscillator 300 in FIG. 3) of benchmark circuits, a plurality of element ratios corresponding to a plurality of basic elements, a driving strength of the basic elements that compose the benchmark circuit, and an operating voltage. The label data includes a speed degradation ratio. In step S1402, a training module to be trained 102 is trained based on the aforementioned training data to obtain numerical values of the parameters that are obtained after training.

In the aforementioned embodiments, by way of training, a plurality of parameters of a neural network model corresponding to the basic elements are obtained, so that the neural network model can be repeatedly used for predicting aging results of various scenarios with different operating voltages and stress times, thus avoiding the repeated real circuit aging simulation, so that resources and time can be saved.

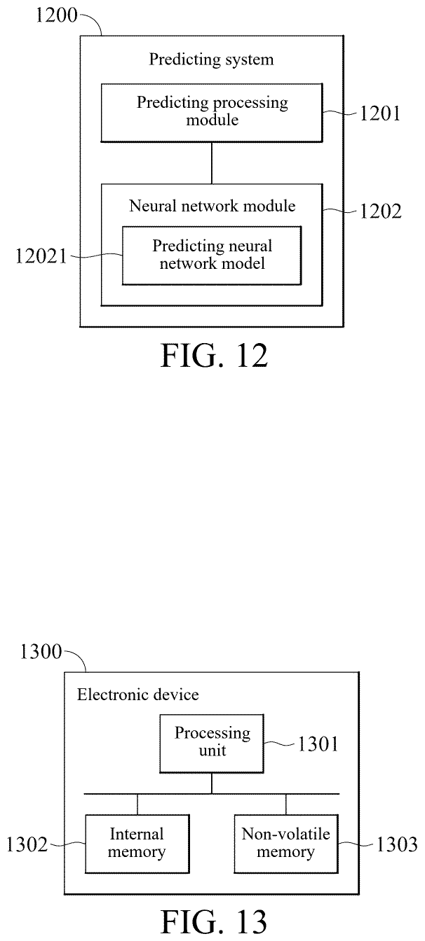

FIG. 15 is a flowchart of a training method illustrated according to some embodiments of the present disclosure. Referring to FIG. 1, FIG. 14, FIG. 15, in some embodiments of the present disclosure, the aforementioned step S1402 includes executing steps S1501 to S1502 in one training epoch. In step S1501, the processing module 101 repeatedly executes the following steps: taking the training input data of current data in the aforementioned at least one piece of training data as the network input of the module to be trained 102; and obtaining a loss based on the network output of the module to be trained 102 and the label data of the current data. In step S1502, the processing module 101 updates the parameters of the module to be trained 102 based on an average of the losses obtained in step S1501 and an updating algorithm employed for the processing module 101.

In some embodiments of the present disclosure, the aforementioned loss uses a mean square error. In some embodiments of the present disclosure, the aforementioned updating algorithm is an adaptive moment estimation (Adam) method. It is worth noting that other updating algorithms can also be employed for the processing module 101, e.g., one of gradient descent (GD), stochastic gradient descent (SGD), momentum, an RMSProp method, and an Adagrad method.

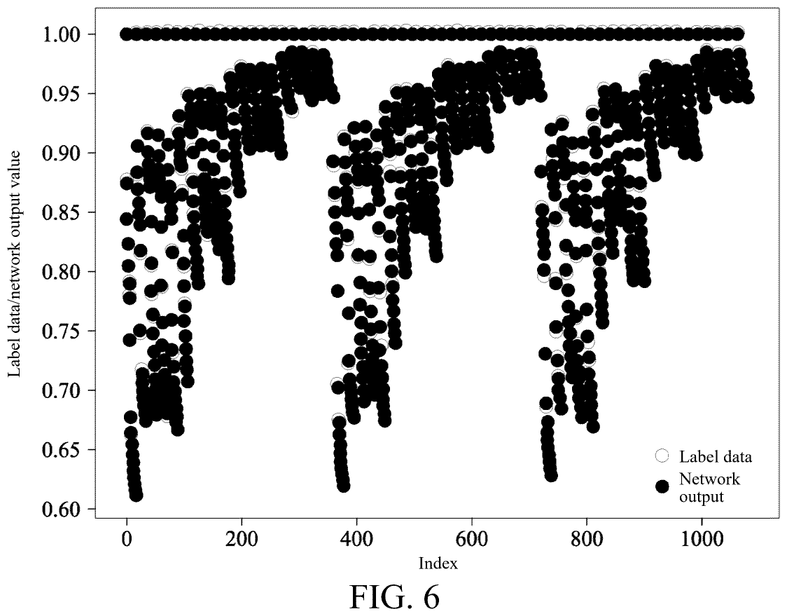

FIG. 6 is a schematic diagram of training results illustrated according to some embodiments of the present disclosure. Referring to FIG. 1 to FIG. 3 and FIG. 6, in this embodiment, the neural network model 103 is as illustrated in FIG. 2, and the activation functions α₁ to α₅ are set as a sigmoid function. At the beginning of training, the processing module 101 randomly sets initial values of the weights of all the aforementioned connection paths, and biases of all the neurons and output neurons based on a probability distribution (e.g., a normal distribution). The processing module 101 can use a random function (e.g., a random( ) function of a random module in Python) provided by general programming languages that is simulated with software to randomly sets initial values of the weights of all the aforementioned connection paths, and biases of all the neurons and output neurons. The aforementioned benchmark circuit 1103 is illustrated as the ring oscillator 300. The aforementioned basic elements include inverter elements, NAND gate elements, NOR gate elements and XOR gate elements. The training input data is illustrated in FIG. 4 (with 1080 sets of data). The number of iterations of the processing module 101 executing training is 10,000 (that is, there are 10,000 training epochs), and the batch size is 90. The aforementioned loss uses a mean square error, and the aforementioned updating algorithm is an adaptive moment estimation method. After training, the processing module 101 can obtain the numerical values of the weights of all the connection paths, and biases of all the neurons and output neurons. FIG. 6 illustrates a comparison result between a network output generated by inputting a training input data illustrated in FIG. 4 as a network input to a neural network model 103 that uses numerical values obtained after training and label data corresponding to the training input data illustrated in FIG. 4, where the horizontal axis is an index of the training input data.

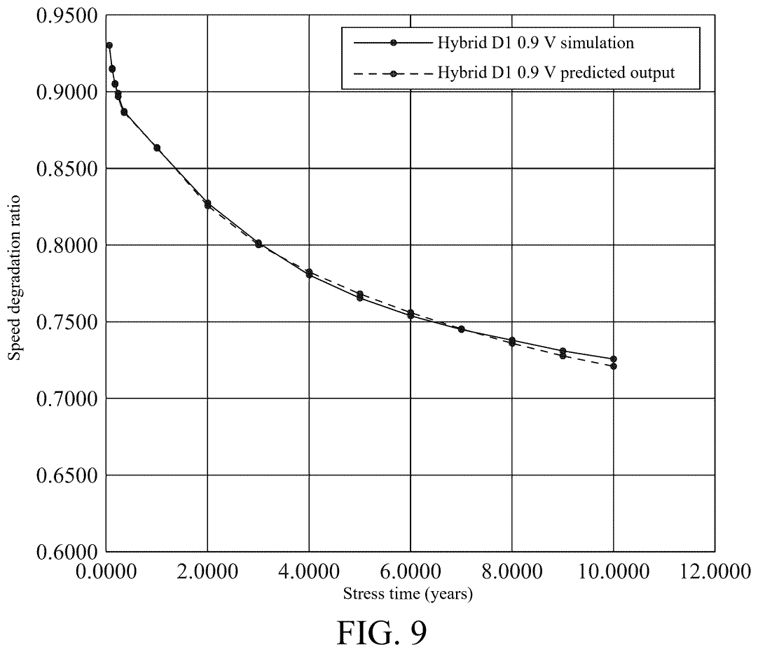

FIG. 12 is a block diagram of a predicting system illustrated according to some embodiments of the present disclosure. Referring to FIG. 12, a predicting system 1200 includes a predicting processing module 1201 and a neural network model 1202. The neural network module 1202 includes a predicting neural network model 12021, where the predicting neural network model 12021 is configured to have the same architecture as that of the neural network model 103. The neural network module 1202 is configured to receive and store a plurality of parameters of the module to be trained 102 that are obtained after the training system 100 completes the training. The neural network module 1202 is configured to receive an input to be predicted and generate a predicted output corresponding to the input to be predicted based on the input to be predicted, the predicting neural network model 12021, and the stored parameters.

The predicting method of some embodiments of the present disclosure and how various modules of the predicting system 1200 cooperate with each other will be described below in detail with the schematics.

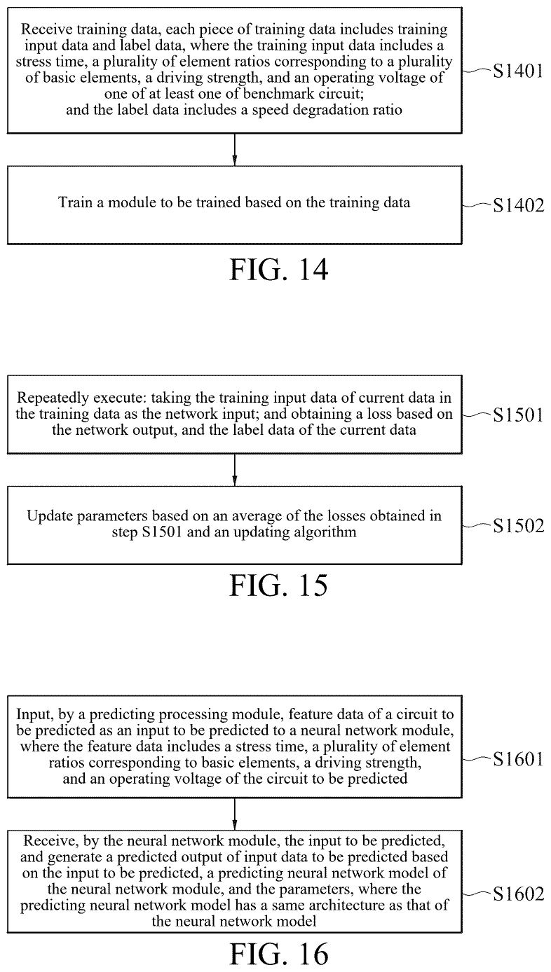

FIG. 16 is a flowchart of a predicting method illustrated according to some embodiments of the present disclosure. Referring to FIG. 11, FIG. 12, and FIG. 16, in the embodiment illustrated in FIG. 16, the predicting method includes steps S1601 to S1602. In step S1601, a predicting processing module 1201 inputs a piece of feature data 1105 of a circuit to be predicted as an input to be predicted to a neural network module 1202, where the feature data 1105 includes a stress time, a plurality of element ratios corresponding to the basic elements, a driving strength, and an operating voltage of the circuit to be predicted. In step S1602, the neural network module 1202 receives an input to be predicted, and generates a predicted output 1106 corresponding to input data to be predicted (the feature data 1105) based on the received input to be predicted, the predicting neural network model 12021 of the neural network module 1202, and the received parameters obtained after the training system 100 completes the training.

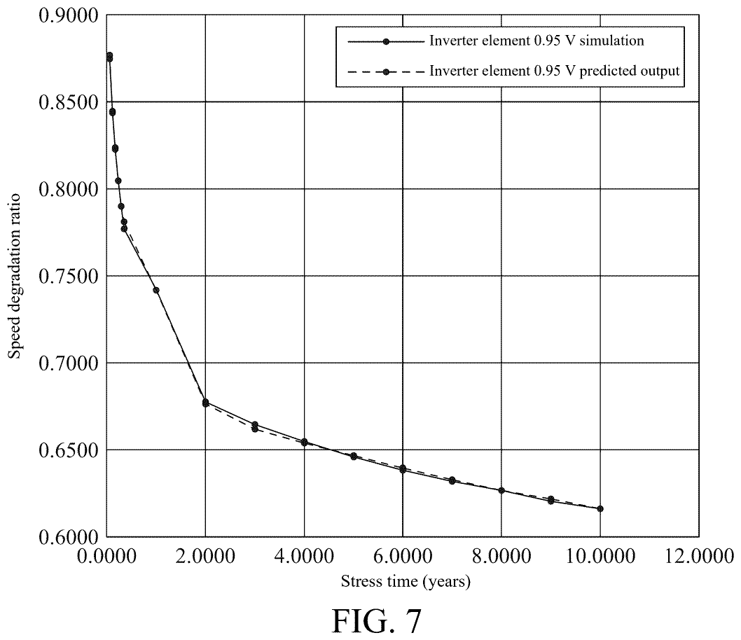

FIG. 7 to FIG. 10 are schematic diagrams showing performance of a predicting system illustrated according to some embodiments of the present disclosure. Referring to FIG. 7 to FIG. 10, following the aforementioned embodiment illustrated in FIG. 6, the neural network module 1202 is configured to receive and store a plurality of parameters of the module to be trained 102 that are obtained after the training system 100 completes the training, and the predicting neural network model 12021 has the same architecture as that of the neural network model 103. FIG. 7 to FIG. 10 illustrate test results of testing the performance of the predicting system 1200 using test data. The structure of the test data is the same as that of the training data, and each of the test data includes test input data and label data. The test input data includes a stress time, a plurality of element ratios corresponding to a plurality of basic elements, a driving strength, and an operating voltage of one of benchmark circuits, where the label data includes a speed degradation ratio of the aforementioned benchmark circuit.

FIG. 7 illustrates a curve (solid line in FIG. 7) composed of the speed degradation ratios of the label data of a plurality of sets of test data and a curve (dashed line in FIG. 7) composed of the predicted outputs of test input data corresponding to the plurality of sets of test data generated by the neural network module 1202. In a plurality of sets of test data in FIG. 7, the numerical values corresponding to the inverter element, the NAND gate element, the NOR gate element, and the XOR gate element are 1.0, 0.0, 0.0, and 0.0, respectively (indicating that the inverter stages 302 to 3033 are all composed of the inverter elements), the numerical values corresponding to the driving strength is 1.0 (indicating that the driving strength of each of the inverter stage 302 to 3033 is D1), and the numerical values corresponding to the operating voltage is 0.95 (indicating that the operating voltage for aging simulation is 0.95 volts.). The stress time of the plurality of sets of test data in FIG. 7 is the horizontal axis coordinate value of each point in FIG. 7.

FIG. 8 illustrates a curve (solid line in FIG. 8) composed of the speed degradation ratios of the label data of a plurality of sets of test data and a curve (dashed line in FIG. 8) composed of the predicted outputs of test input data corresponding to the plurality of sets of test data generated by the neural network module 1202. In a plurality of sets of test data in FIG. 8, the numerical values corresponding to the inverter element, the NAND gate element, the NOR gate element, and the XOR gate element are 1.0, 0.0, 0.0, and 0.0, respectively, the numerical values corresponding to the driving strength is 1.0, and the numerical values corresponding to the operating voltage is 0.85 (indicating that the operating voltage for aging simulation is 0.85 volts.). The stress time of the plurality of sets of test data in FIG. 8 is the horizontal axis coordinate value of each point in FIG. 8.

FIG. 9 illustrates a curve (solid line in FIG. 9) composed of the speed degradation ratios of the label data of a plurality of sets of test data and a curve (dashed line in FIG. 9) composed of the predicted outputs of test input data corresponding to the plurality of sets of test data generated by the neural network module 1202. In a plurality of sets of test data in FIG. 9, the numerical values corresponding to the inverter element, the NAND gate element, the NOR gate element, and the XOR gate element are not 1 (indicating that the inverter stages 302 to 3033 are each composed of a hybrid of the inverter elements, the NAND gate elements, the NOR gate elements, and the XOR gate elements), the numerical values corresponding to the driving strength is 1.0 (indicating that the driving strength of each of the inverter stage 302 to 3033 is D1), and the numerical values corresponding to the operating voltage is 0.9 (indicating that the operating voltage for aging simulation is 0.9 V). The stress time of the plurality of sets of test data in FIG. 9 is the horizontal axis coordinate value of each point in FIG. 9.

FIG. 10 illustrates a curve (solid line in FIG. 10) composed of the speed degradation ratios of the label data of a plurality of sets of test data and a curve (dashed line in FIG. 10) composed of the predicted outputs of test input data corresponding to the plurality of sets of test data generated by the neural network module 1202. In a plurality of sets of test data in FIG. 10, the numerical values corresponding to the inverter element, the NAND gate element, the NOR gate element, and the XOR gate element are not 1 (indicating that the inverter stages 302 to 3033 are each composed of a hybrid of the inverter elements, the NAND gate elements, the NOR gate elements, and the XOR gate elements), the numerical values corresponding to the driving strength is 2.0 (indicating that the driving strength of each of the inverter stage 302 to 3033 is D2), and the numerical values corresponding to the operating voltage is 0.9 (indicating that the operating voltage for aging simulation is 0.9 volts.). The stress time of the plurality of sets of test data in FIG. 10 is the horizontal axis coordinate value of each point in FIG. 10.

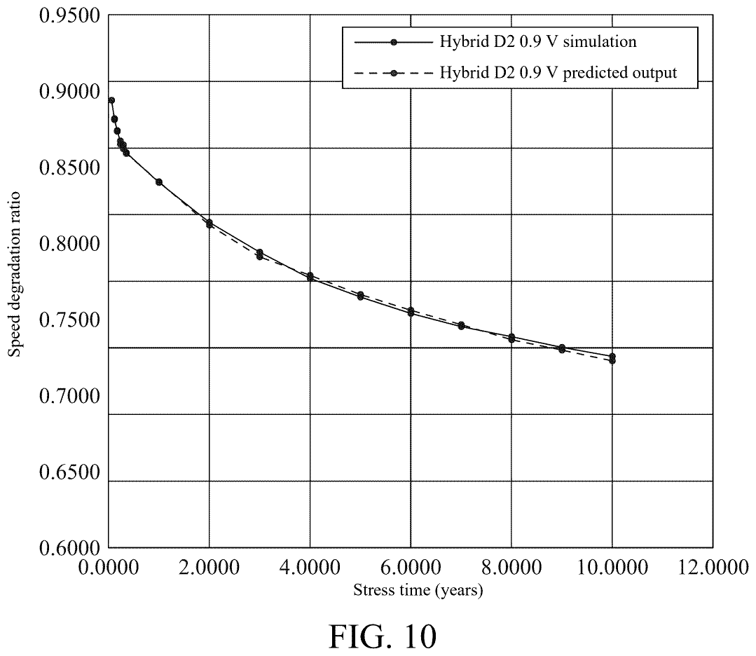

FIG. 13 is a systematic block schematic diagram of an electronic device illustrated according to some embodiments of the present disclosure. As shown in FIG. 13, at a hardware level, an electronic device 1300 includes a processing unit 1301, an internal memory 1302, and a non-volatile memory 1303. The internal memory 1302 is, for example, a random-access memory (RAM). The non-volatile memory 1303 is, for example, at least one magnetic disc memory and the like. Of course, the electronic device 1300 may further include hardware required for other functions.

The internal memory 1302 and the non-volatile memory 1303 are configured to store a program that may include a program code, where the program code includes a computer operating instruction. The internal memory 1302 and the non-volatile memory 1303 provide instructions and data to the processing unit 1301. The processing unit 1301 reads a corresponding computer program from the non-volatile memory 1303 into the internal memory 1302 and then runs the computer program, thus forming the training system 100 or the predicting system 1200 at a logic level.

The processing unit 1301 may be an integrated circuit chip, which has signal processing capacity. In the implementation process, various methods and steps disclosed in the aforementioned embodiments can be implemented by an integrated logic circuit of hardware in the processing unit 1301 or an instruction in a software form. The processing unit 1301 may be a graphics processor or a general-purpose processor, including a central processing unit, a digital signal processor, an application specific integrated circuit, a field-programmable gate array, or other programmable logic devices. The processing unit can implement or execute the methods and steps disclosed in the aforementioned embodiments.

An embodiments of this description further provides a computer-readable storage medium storing at least one instruction which, when executed by the processing unit 1301 of the electronic device 1300, enables the processing unit 1301 of the electronic device 1300 to execute the various methods and steps disclosed in the aforementioned embodiments.

Examples of storage media for computers include, but are not limited to, a phase change random-access memory (PRAM), a static random-access memory (SRAM), a dynamic random-access memory (DRAM), other types of random-access memories (RAM), a read-only memory (ROM), an electrically erasable programmable read-only memory (EEPROM), a flash memory or other internal memory technologies, a compact disc read-only memory (CD-ROM), a digital versatile disc (DVD) or other optical storages, a magnetic cassette tape, a magnetic tape disk storage or other magnetic storage devices, or any other non-transmission media, which can be used for storing information that can be accessed by a computing device. As defined herein, computer-readable media do not include transitory media, such as modulated data signals and carriers.

Based on the above, some embodiments of the present disclosure provide a training system, a training method, a predicting system, a predicting method, a computer-readable recording medium with a stored program, and a non-transitory computer program product. By way of training, a plurality of parameters of a neural network model corresponding to basic elements are obtained, and a predicting system applying the aforementioned neural network model and the plurality of parameters of the neural network model can predict a speed degradation ratio when an aging model is not provided in a laboratory; the predicting system applying the aforementioned neural network model and the plurality of parameters of the neural network model can be repeatedly used for predicting aging results of various scenarios with different operating voltages and stress times, thus avoiding the repeated real circuit aging simulation, so that resources and time can be saved.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A training system, comprising:
a processing module, configured to receive at least one piece of training data, wherein each piece of training data comprises training input data and label data, the training input data comprises a stress time, a plurality of element ratios corresponding to a plurality of basic elements, a driving strength, and an operating voltage of one of at least one benchmark circuit, and the label data comprises a speed degradation ratio; and
a module to be trained, comprising a neural network model and a plurality of parameters, wherein the module to be trained is configured to receive a network input and generate a network output based on the network input, the neural network model and the parameters; and
the processing module being configured to train the module to be trained based on the at least one piece of training data.

2. The training system according to claim 1, wherein the step of training the module to be trained based on the at least one piece of training data comprises executing the following sub-steps in one training epoch:
(a) repeatedly executing: taking the training input data of a piece of current data in the at least one piece of training data as the network input; and obtaining a loss based on the network output, and the label data of the current data; and
(b) updating the parameters based on an average of the losses obtained in step (a) and an updating algorithm.

3. The training system according to claim 2, wherein the loss uses a mean square error.

4. The training system according to claim 2, wherein the updating algorithm is an adaptive moment estimation (Adam) method.

5. The training system according to claim 1, wherein the neural network model comprises an input layer, four hidden layers, and an output layer that are connected in a fully-connected manner, the input layer being configured to receive the network input, and the output layer being configured to output the network output.

6. The training system according to claim 1, wherein each of the at least one benchmark circuit is a ring oscillator, the ring oscillator comprising an enable stage and an even number of inverter stages, each of the inverter stages having a same driving strength and each of the inverter stages being composed of one of the basic elements, and the element ratios are a plurality of composition ratios of the inverter stages corresponding to the basic elements.

7. The training system according to claim 6, wherein the basic elements comprise inverter elements, NAND gate elements, NOR gate elements and XOR gate elements.

8. The training system according to claim 6, wherein a number of the inverter stages is 32.

9. A predicting system using the parameters obtained by training by the training system according to claim 1, comprising:
a neural network module, comprising a predicting neural network model, wherein the predicting neural network model is configured to have a same architecture as that of the neural network model, and the neural network module is configured to store the parameters obtained after training and is configured to receive an input to be predicted, and generate a predicted output of the input to be predicted based on the input to be predicted, the predicting neural network model and the parameters; and
a predicting processing module, configured to input a piece of feature data of a circuit to be predicted as the input to be predicted to the neural network module to obtain the predicted output, wherein the feature data comprises a stress time of the circuit to be predicted, a plurality of element ratios corresponding to the basic elements, a driving strength, and an operating voltage.

10. A training method, used for training a module to be trained, and executed by a processing module, wherein the module to be trained comprises a neural network model and a plurality of parameters; the module to be trained is configured to receive a network input and generate a network output based on the network input, the neural network model, and the parameters; and the training method comprises executing the following steps:
(a) receiving at least one piece of training data, wherein each piece of training data comprises training input data and label data, the training input data comprises a stress time, a plurality of element ratios corresponding to a plurality of basic elements, a driving strength, and an operating voltage of one of at least one benchmark circuit, and the label data comprises a speed degradation ratio; and
(b) training the module to be trained based on the at least one piece of training data.

11. The training method according to claim 10, wherein the step (b) comprises executing the following sub-steps in one training epoch:
(b1) repeatedly executing: taking the training input data of a piece of current data in the at least one piece of training data as the network input; and obtaining a loss based on the network output, and the label data of the current data; and
(b2) updating the parameters based on an average of the losses obtained in step (b1) and an updating algorithm.

12. The training method according to claim 11, wherein the loss uses a mean square error.

13. The training method according to claim 11, wherein the updating algorithm is an adaptive moment estimation (Adam) method.

14. The training method according to claim 10, wherein the neural network model comprises an input layer, four hidden layers, and an output layer that are connected in a fully-connected manner, the input layer being configured to receive the network input, and the output layer being configured to output the network output.

15. The training method according to claim 10, wherein each of the at least one benchmark circuit is a ring oscillator, the ring oscillator comprising an enable stage and an even number of inverter stages, each of the inverter stages having a same driving strength and each of the inverter stages being composed of one of the basic elements, and the element ratios are a plurality of composition ratios of the inverter stages corresponding to the basic elements.

16. The training method according to claim 15, wherein the basic elements comprise inverter elements, NAND gate elements, NOR gate elements and XOR gate elements.

17. The training method according to claim 15, wherein a number of the inverter stages is 32.

18. A predicting method using the parameters obtained by training by the training method according to claim 10, comprising:
inputting, by a predicting processing module, a piece of feature data of a circuit to be predicted as an input to be predicted to a neural network module, wherein the feature data comprises a stress time of the circuit to be predicted, a plurality of element ratios corresponding to the basic elements, a driving strength, and an operating voltage; and
receiving, by the neural network module, the input to be predicted, and generating a predicted output of input data to be predicted based on the input to be predicted, a predicting neural network model of the neural network module, and the parameters obtained after training, wherein the predicting neural network model has a same architecture as that of the neural network model.

19. A non-transitory computer-readable recording medium with a stored program, wherein the stored program, after loaded and executed by a processing unit, implements the method according to claim 10.

20. A non-transitory computer program product storing at least one instruction which, when executed by a processing unit, causes the processing unit to execute the method according to claim 10.
